(19) United States
(12) Patent Application Publication
(10) Pub. No.: US 2025/0133932 A1
(43) Pub. Date: Apr. 24, 2025

(54) DISPLAY DEVICE AND METHOD FOR MANUFACTURING THE SAME

(71) Applicant: Samsung Display Co., LTD., Yongin-si (KR)

(72) Inventors: SANGDUK LEE, Yongin-si (KR); HYUNKYUNG YUN, Yongin-si (KR); HOIKWAN LEE, Yongin-si (KR)

(21) Appl. No.: 18/886,429

(22) Filed: Sep. 16, 2024

(30) Foreign Application Priority Data
Oct. 20, 2023 (KR) 10-2023-0141000

(51) Int. Cl. H10K 59/80; H10K 59/40

(52) U.S. Cl. CPC H10K 59/871; H10K 59/40

(57) ABSTRACT

A display device includes a display panel, a coating window disposed on the display panel, and a functional layer disposed on the coating window formed from a thermosetting coating solution. The functional layer may include a UV absorber in an amount of about 1 wt % to about 10 wt % with respect to the total weight of the functional layer, and the UV absorber may include an organic material.

This application claims priority to Korean Patent Application No. 10-2023-0141000, filed on Oct. 20, 2023, and all the benefits accruing therefrom under 35 U.S.C. § 119, the content of which in its entirety is herein incorporated by reference.

### BACKGROUND

### 1. Field

The present invention relates to a display device, and more particularly to a display device including a coating window and a method for manufacturing the same.

### 2. Description of the Related Art

Various display devices used for multimedia devices such as a television, a mobile phone, a tablet computer, and a game console are being developed. A display device may include a display panel which generates images and videos, and a window member for protecting the display panel. The window member, which is disposed on an uppermost part of the display device, should be configured to maintain reliability in consideration of a usage environment of the display device.

### SUMMARY

The present invention provides a display device with improved reliability and a method for manufacturing the same.

An embodiment of the invention provides a display device including a display panel, a coating window disposed on the display panel, and a functional layer disposed on the coating window and formed from a thermosetting coating solution, wherein the functional layer includes an ultraviolet (UV) absorber in an amount of about 1 wt % to about 10 wt % with respect to the total weigh of the functional layer, and the UV absorber includes an organic material.

In an embodiment, the functional layer further may include a base resin and a fluorine-containing compound.

In an embodiment, the base resin may include an acryl-based resin.

In an embodiment, the UV absorber may include at least one of a stilbene-based derivative, a phenylenevinylene-based derivative, a benzoxazole-based derivative, a benzotriazole-based derivative, a benzophenone-based derivative, or a triazine-based derivative.

In an embodiment, the functional layer may have a pencil hardness of about 6 H or more.

In an embodiment, the functional layer may have a yellow index of about 1 or less.

In an embodiment, the functional layer may have a transmittance of about 90% or more with respect to light having a visible light wavelength range.

In an embodiment, the functional layer may be a single layer.

In an embodiment, the functional layer may be directly disposed on the coating window.

In an embodiment, the coating window may include an epoxy-based resin.

In an embodiment of the invention, a method for manufacturing a display device includes preparing a display panel, forming a coating window on the display panel and forming a functional layer by providing a thermosetting coating solution on the coating window, wherein the thermosetting coating solution includes a UV absorber in an amount of about 1 wt % to about 10 wt % with respect to the total weight of the thermosetting coating solution, and the UV absorber includes an organic material.

In an embodiment, the thermosetting coating solution may be directly provided on the coating window.

In an embodiment, the thermosetting coating solution further may include a base resin and a fluorine-containing compound.

In an embodiment, the base resin may include an acryl-based resin.

In an embodiment, the UV absorber may include at least one of a stilbene-based derivative, a phenylenevinylene-based derivative, a benzoxazole-based derivative, a benzotriazole-based derivative, a benzophenone-based derivative, or a triazine-based derivative.

In an embodiment, the forming of the functional layer may include forming a preliminary functional layer by providing the thermosetting coating solution on the coating window and forming the functional layer by curing the preliminary functional layer, and the curing of the preliminary functional layer is performed at a temperature of about 20° C. to about 80° C.

In an embodiment, in the forming of the preliminary functional layer, a curing rate may be about 90% or more.

In an embodiment, the thermosetting coating solution may be provided through roll coating, silk screen coating, spray coating, or slit coating.

In an embodiment, the coating window may be formed by providing a coating composition on the display panel.

In an embodiment, the coating composition may include an epoxy-based resin.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a perspective view illustrating a display device, according to an embodiment;

FIG. 2 is an exploded perspective view of a display device, according to an embodiment;

FIG. 3 is a cross-sectional view illustrating a portion of a window member of a display device corresponding to line I-I′ of FIG. 2, according to an embodiment;

FIG. 4 is a cross-sectional view illustrating a portion of a display device, according to an embodiment;

FIG. 5 is a flowchart illustrating a method for manufacturing a display device, according to an embodiment;

FIG. 6 is a view schematically illustrating a display device manufacturing step, according to an embodiment;

FIG. 7 is a view schematically illustrating a display device manufacturing step, according to an embodiment;

FIG. 8 is a view schematically illustrating a display device manufacturing step, according to an embodiment; and

FIG. 9 is a view schematically illustrating a display device manufacturing step, according to an embodiment.

### DETAILED DESCRIPTION

The invention may be implemented in various modifications and have various forms, and specific embodiments are illustrated in the drawings and described in detail in the text. It is to be understood, however, that the invention is not intended to be limited to the particular forms disclosed, but on the contrary, is intended to cover all modifications, equivalents, and alternatives falling within the spirit and scope of the invention.

In this specification, it will be understood that when an element (or region, layer, portion, or the like) is referred to as being “on”, “connected to” or “coupled to” another element, it may be directly disposed/connected/coupled to another element, or intervening elements may be disposed therebetween.

Like reference numerals or symbols refer to like elements throughout. Also, in the drawings, the thicknesses, the ratios, and the dimensions of the elements may be exaggerated for effective description of the technical contents. The term “and/or” includes all combinations of one or more of the associated listed elements.

Although the terms first, second, etc., may be used to describe various elements, these elements should not be limited by these terms. These terms are only used to distinguish one element from another element. For example, a first element may be referred to as a second element, and similarly, a second element may also be referred to as a first element without departing from the scope of the inventive concept. The singular forms include the plural forms as well, unless the context clearly indicates otherwise.

Also, the terms such as “below”, “lower”, “above”, “upper” and the like, may be used for the description to describe one element's relationship to another element illustrated in the figures. It will be understood that the terms have a relative concept and are described on the basis of the orientation depicted in the figures.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

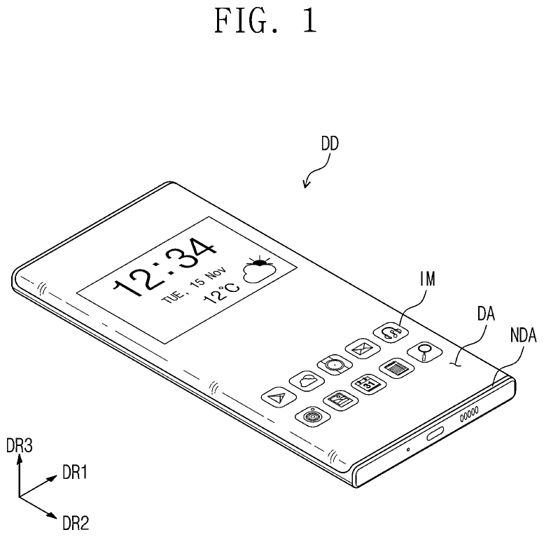

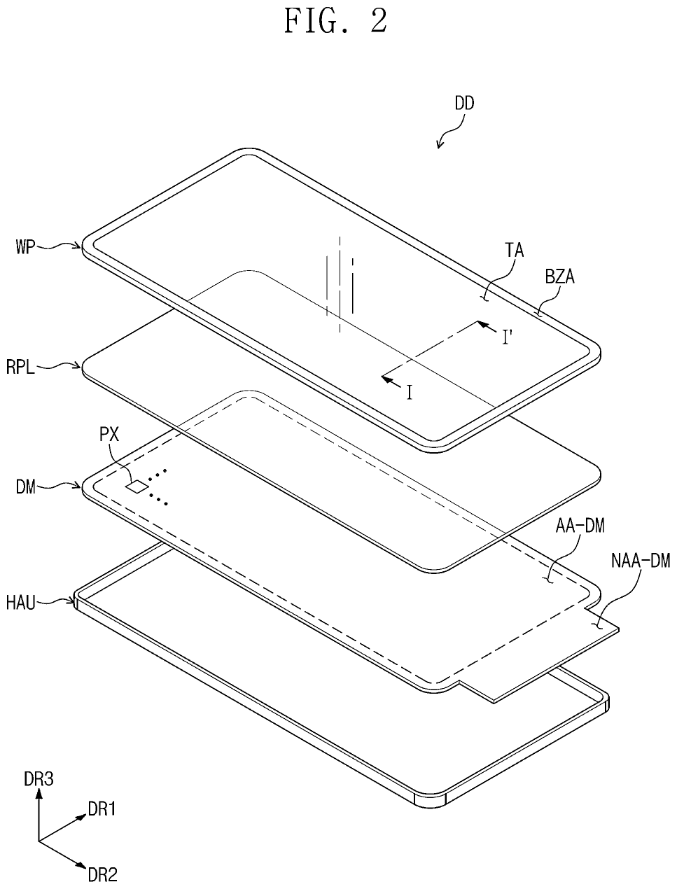

Hereinafter, a display device, according to an embodiment, will be described with reference to the accompanying drawings. FIG. 1 is a perspective view illustrating a display device, according to an embodiment. FIG. 2 is an exploded perspective view of a display device, according to an embodiment.

A display device DD, according to an embodiment which is illustrated in FIG. 1, may be activated in response to an electrical signal. For example, the display device DD may be a personal computer, a laptop computer, a personal digital terminal, a game console, a portable electronic device, a television, a monitor, an outdoor billboard, a car navigation unit, or a wearable device, but the invention is not limited thereto. In FIG. 1, the display device DD is exemplarily illustrated as a mobile phone.

The display device DD, according to an embodiment, may display an image IM through a display region DA. The display region DA may include a flat surface defined by a first direction axis DR1 and a second direction axis DR2. The display region DA may include a curved surface bent from at least one side of the flat surface defined by a first direction axis DR1 and a second direction axis DR2. It is illustrated that the display device DD, according to an embodiment, which is illustrated in FIG. 1, includes two curved surfaces which are respectively bent from both sides of the flat surface defined by the first direction axis DR1 and the second direction axis DR2. However, this is presented as an example, and a shape of the display region DA is not limited thereto. For example, in other embodiments, the display region DA may include only the flat surface defined by the first direction axis DR1 and the second direction axis DR2, or may further include at least two curved surfaces, for example, four curved surfaces respectively bent from four side surfaces of the flat surface defined by the first direction axis DR1 and the second direction axis DR2.

The display device DD, according to an embodiment, may be flexible. The wording “flexible” means having a bendable property, and may include all of a completely foldable structure as well as a structure which is bendable to the level of several nanometers. For example, the display device DD may be foldable. Additionally, the display device DD may be rigid.

In an embodiment, a non-display region NDA may be disposed adjacent to the display region DA. The non-display region NDA may surround the display region DA. Accordingly, a shape of the display region DA may be substantially defined by the non-display region NDA. However, this is exemplarily illustrated. The non-display region NDA may be disposed to be adjacent to only one side of the display region DA or may be omitted. The display region DA may be provided to have various shapes and is not limited to any one embodiment.

In FIG. 1 and the following drawings, a first direction axis DR1 to a third direction axis DR3 are illustrated, and directions indicated by the first to third direction axes DR1, DR2, and DR3, respectively, described herein may have a relative concept, and thus may be changed to other directions. In addition, the directions indicated by the first to third direction axes DR1, DR2, and DR3, respectively, may be referred to as first to third directions, and may be denoted as the same reference numerals or symbols. In this specification, the first direction axis DR1 and the second direction axis DR2 may be orthogonal to each other, and the third direction axis DR3 may be parallel to a normal direction of a plane defined by the first direction axis DR1 and the second direction axis DR2.

A thickness direction of the display device DD may be directed parallel to the third direction axis DR3 which is the normal direction of the plane defined by the first direction axis DR1 and the second direction axis DR2. In this specification, a front surface (or upper surface, top surface, upper side) and a rear surface (or lower surface, bottom surface, lower side) of each member constituting the display device DD may be defined based on the third direction axis DR3. In this specification, a direction in which the third direction axis DR3 extends is parallel to a thickness direction. The front surface (or upper surface, top surface, upper side) means a surface (or direction getting closer to) that is adjacent to a surface on which an image IM is displayed, and the rear surface (or lower surface, bottom surface, lower side) means a surface (or a direction getting farther away from) that is spaced apart from a surface on which the image IM is displayed.

In an embodiment and referring to FIG. 2, a display device DD may include a display module DM, and a window member WP disposed on the display module DM. Additionally, the display device DD may further include an optical layer RPL disposed between the display module DM and the window member WP, and a housing HAU which accommodates the display module DM.

In an embodiment, in the display device DD illustrated in FIGS. 1 and 2, the window member WP and the housing HAU may be coupled together to constitute the exterior of the display device DD. The housing HAU may be disposed under the display module DM. The housing HAU may include a material having relatively high rigidity. For example, the housing HAU may include a plurality of frames and/or plates composed of glass, plastic, or metal. The housing HAU may provide a predetermined accommodation space. The display module DM may be accommodated inside the accommodation space and protected against an external impact.

In an embodiment, the display module DM may be activated in response to an electrical signal. The display module DM may be activated to display the image IM (see FIG. 1) on the display region DA (see FIG. 1) of the display device DD. An active region AA-DM and a peripheral region NAA-DM may be defined in the display module DM. The active region AA-DM may be activated in response to an electrical signal. The peripheral region NAA-DM may be located to be adjacent to at least one side of the active region AA-DM. A circuit, wiring, or the like for driving the active region AA-DM may be disposed in the peripheral region NAA-DM.

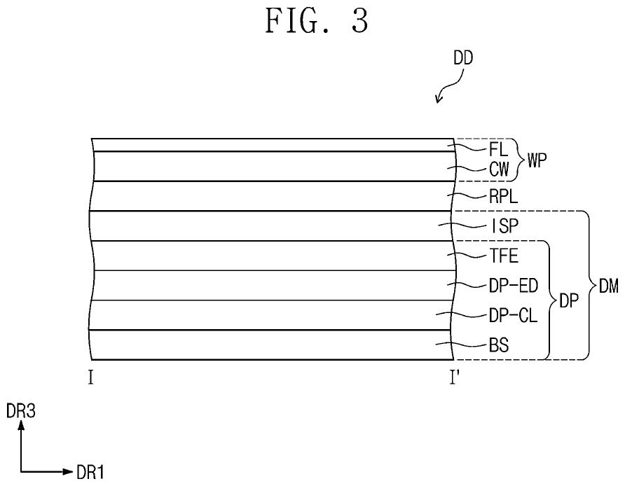

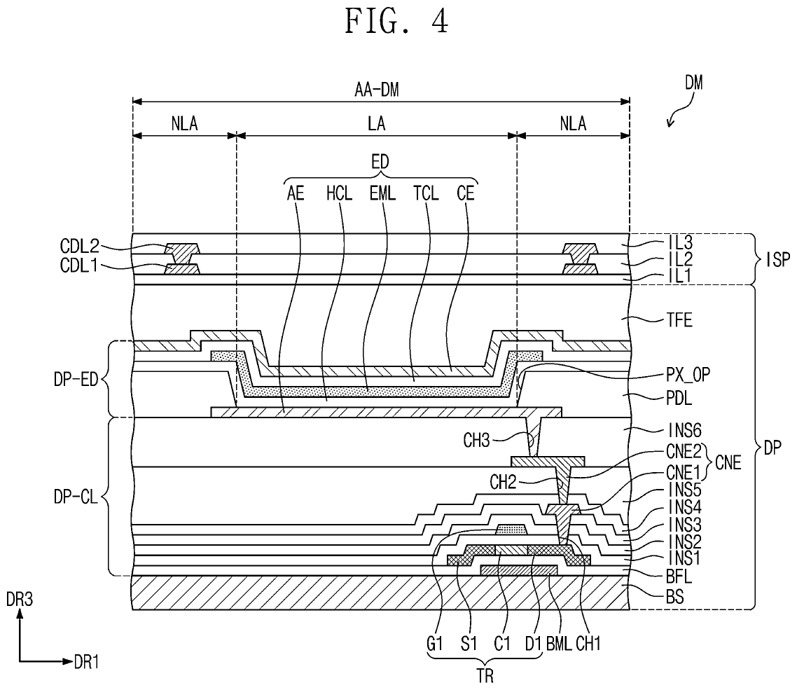

In an embodiment, the optical layer RPL may be an anti-reflective layer which reduces reflectance of external light incident from the outside of the display module DM. The optical layer RPL may be formed on the display module DM through a continuous process. The optical layer RPL may include a polarizing plate or a color filter layer. For example, the optical layer RPL may include at least one of a retarder, a polarizer, a polarizing film, or a polarizing filter. In another embodiment, the optical layer RPL may include a plurality of color filters disposed in a predetermined arrangement. For example, the color filters may be arranged in consideration of emission colors of pixels included in a display panel DP (see FIGS. 3 and 4) to be described later. Additionally, the optical layer RPL may further include a black matrix disposed adjacent to the color filters. Unlike what is illustrated, in another embodiment, the optical layer RPL may be omitted.

In an embodiment, the window member WP may include a transmission region TA and a bezel region BZA. The transmission region TA may overlap at least a portion of the active region AA-DM of the display module DM. The transmission region TA may be an optically transparent region. The image IM (see FIG. 1) may be provided to a user through the transmission region TA.

In an embodiment, the bezel region BZA may be a region having a relatively lower light transmittance than the transmission region TA. The bezel region BZA may define a shape of the transmission region TA. The bezel region BZA may be disposed adjacent to the transmission region TA and may surround the transmission region TA.

In an embodiment, the bezel region BZA may have a predetermined color. The bezel region BZA may cover the peripheral region NAA-DM of the display module DM and block the peripheral region NAA-DM from being viewed from the outside. However, the invention is not limited to what is illustrated in the drawings. In another embodiment, the bezel region BZA may be disposed adjacent to only one side of the transmission region TA, or at least a portion thereof may be omitted.

FIG. 3 is a cross-sectional view illustrating a portion of the window member WP of the display device DD corresponding to line I-I′ of FIG. 2, according to an embodiment, and for ease of description, the housing HAU is omitted. FIG. 3 is a cross-sectional view illustrating a display module DM, according to an embodiment.

In an embodiment and referring to FIG. 3, a display module DM may include a display panel DP and an input-sensing layer ISP disposed on the display panel DP. The display panel DP may be configured to substantially generate an image.

In an embodiment, the display panel DP may include a base layer BS, a circuit layer DP-CL, a display element layer DP-ED, and an encapsulation layer TFE, which are sequentially stacked. Unlike what is illustrated, in another embodiment, an additional member may be further disposed between two adjacent layers among the base layer BS, the circuit layer DP-CL, the display element layer DP-ED, and the encapsulation layer TFE.

In an embodiment, the base layer BS may provide a base surface on which the circuit layer DP-CL is disposed. The base layer BS may be a flexible substrate which is bendable, foldable, rollable, or the like. The base layer BS may be a glass substrate, a metal substrate, a polymer substrate, or like. However, the invention is not limited thereto, and the base layer BS may include an inorganic layer, an organic layer, or a composite material layer.

In an embodiment, the base layer BS may have a single- or multi-layered structure. For example, the base layer BS may include a first synthetic resin layer, a multi- or single-layered inorganic layer, or a second synthetic resin layer disposed on the multi- or single-layered inorganic layer. The first synthetic resin layer and the second synthetic resin layer may each include a polyimide-based resin. Additionally, the first synthetic resin layer and the second synthetic resin layer may each include at least one of an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, or a perylene-based resin. In this specification, a “˜˜based” resin may be considered as including a functional group of “˜˜”.

In an embodiment, the circuit layer DP-CL may be disposed on the base layer BS. The circuit layer DP-CL may include an insulating layer, a semiconductor pattern, a conductive pattern, a signal line, and the like. The display element layer DP-ED may be disposed on the circuit layer DP-CL. The display element layer DP-ED may include a light-emitting element ED to be described later (see FIG. 4). For example, the light-emitting element ED (see FIG. 4) may include an organic light-emitting material, an inorganic light-emitting material, an organic-inorganic light-emitting material, quantum dots, quantum rods, a micro LED, or a nano LED.

In an embodiment, the encapsulation layer TFE may be disposed on the display element layer DP-ED. The encapsulation layer TFE may protect the display element layer DP-ED against moisture, oxygen, and foreign substances such as dust particles. The encapsulation layer TFE may include at least one inorganic layer. For example, the encapsulation layer TFE may include an inorganic layer, an organic layer, and an inorganic layer which are sequentially stacked.

In an embodiment, the input-sensing layer ISP may be disposed on the display panel DP. The input-sensing layer ISP may be directly disposed on the encapsulation layer TFE. In another embodiment, an adhesive member may be disposed between the input-sensing layer ISP and the display panel DP.

In this specification, when an element is referred to as being directly disposed/provided on another element, there are no intervening elements disposed therebetween. That is, the wording, “an element is ‘directly disposed on’ another element” may mean that an element is ‘in contact with’ another element.

In an embodiment, the input-sensing layer ISP may detect an external input, change the detected external input to a predetermined input signal, and provide the input signal to the display panel DP. For example, the input-sensing layer ISP may be a touch-sensing layer which detects a touch. The input-sensing layer ISP may recognize a direct touch by a user, an indirect touch by a user, a direct touch by an object, an indirect touch by an object, or the like.

In an embodiment, the input-sensing layer ISP may detect at least one of a position or intensity (pressure) of a touch applied from the outside. The input-sensing layer ISP may have various structures or be composed of various materials, but is not limited to any one embodiment. For example, in an embodiment, the input-sensing layer ISP may detect an external input in a capacitive manner. The display panel DP may receive input signals from the input-sensing layer ISP and generate images corresponding to the input signals. For example, the optical layer RPL may be formed on the input-sensing layer ISP through a continuous process.

In an embodiment, the window member WP may include a coating window CW and a functional layer FL disposed on the coating window CW. The coating window CW may be disposed on the display panel DP, and the functional layer FL may be disposed on the coating window CW.

Although not illustrated, in an embodiment, the window member WP may further include a printing layer corresponding to the bezel region BZA (see FIG. 2). The printing layer may be provided on a lower surface of the coating window CW, and may be disposed in an edge region of the coating window CW. The printing layer may be formed by providing a pigment or dye.

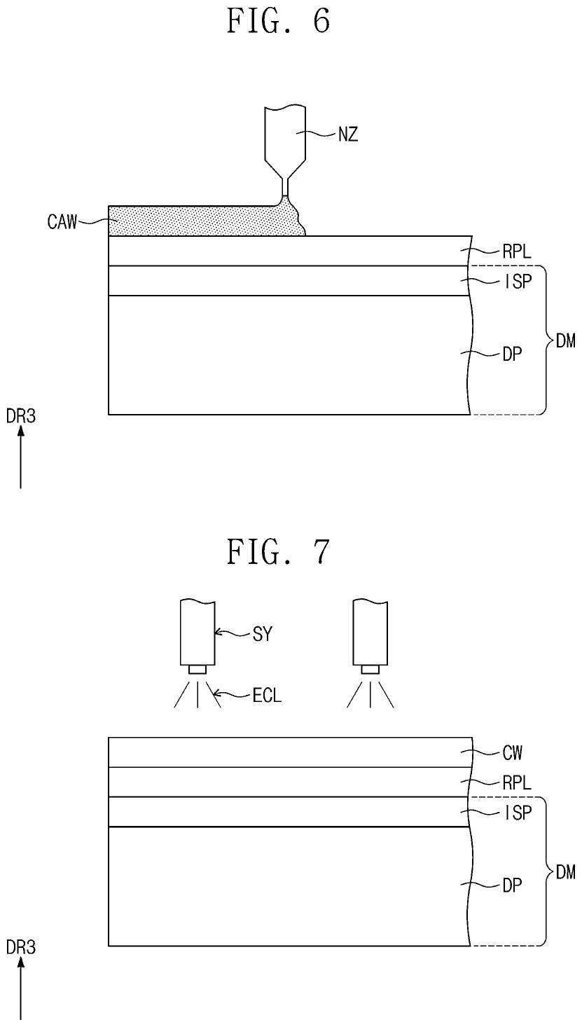

In an embodiment, the coating window CW may include an optically transparent insulating material. For example, the coating window CW may include an epoxy-based resin. In a later-described method for manufacturing a display device, according to an embodiment, the coating window CW may be formed by providing a liquid coating composition CAW (see FIG. 6). The coating window CW is formed by applying the liquid coating composition CAW (see FIG. 6) and may not include a glass substrate. A typical display device is manufactured by providing, on a display panel, a window including a glass substrate. A window including a glass substrate is attached to a display panel through a lamination process, and an adhesive member for attaching the window is required. On the contrary, in another embodiment, the coating window CW may be formed by providing the coating composition CAW which does not require an attachment process, an adhesive member, etc., thereby contributing to improving manufacturing efficiency and reducing a thickness of a display device.

In an embodiment, the functional layer FL may be directly disposed on the coating window CW. The functional layer FL may be a component which is disposed on the uppermost part of the display device DD. The functional layer FL may perform functions of hard coating, anti-fingerprint, and the like. The functional layer FL may be a single layer.

In an embodiment, the functional layer FL may be optically transparent. The functional layer FL may have a transmittance of about 90% or more with respect to light having a visible light wavelength range. The functional layer FL may have a transmittance of about 90% or more with respect to light having a wavelength range of about 380 nm to about 780 nm.

In an embodiment, the functional layer FL may have a pencil hardness of about 6 H or more. For example, the pencil hardness of the functional layer FL may be measured in accordance with the ASTM D3363 method. The functional layer FL may have a yellow index of about 1 or less. For example, the yellow index of the functional layer FL may be measured in accordance with the ASTM E313 method.

In an embodiment, the functional layer FL, having a pencil hardness of 6 H or more and a yellow index of 1 or less, may exhibit excellent wear resistance and scratch resistance. Therefore, the display device DD including the functional layer FL may exhibit excellent reliability.

In an embodiment, the functional layer FL may be formed by providing a thermosetting coating solution ECL to be described later (see FIG. 7). The thermosetting coating solution ECL (see FIG. 7) may include a base resin, a fluorine-containing compound, and an ultraviolet (UV) absorber. The UV absorber may be included in an amount of about 1 wt % to about 10 wt % with respect to the total weight of the thermosetting coating solution ECL (see FIG. 7). The functional layer FL formed from the thermosetting coating solution ECL (see FIG. 7) may include the UV absorber in an amount of about 1 wt % to about 10 wt % with respect to the total weight of the functional layer FL. For example, the functional layer FL may include the UV absorber in an amount of about 2 wt % to about 5 wt % or in an amount of about 3 wt % to about 4 wt % with respect to the total weight of the functional layer FL. The functional layer FL may be formed not from a photocurable coating solution, but from a thermosetting coating solution, and may include the UV absorber in an amount of about 1 wt % or more.

In an embodiment, when the functional layer is formed by providing a thermosetting coating solution including the UV absorber in an amount of less than about 1 wt % with respect to the total weight of the functional layer, yellowing of a coating window, etc., is caused, and thus reliability of the display device is reduced. The yellowing means that a color of a component (or member) becomes yellow over time. Meanwhile, when the functional layer is formed by providing a thermosetting coating solution including the UV absorber in an amount of more than about 10 wt % with respect to the total weight of the functional layer, an acryl-based resin and/or a fluorine-containing compound decrease(s) in weight, and thus the properties of the functional layer (for example, wear resistance, anti-fingerprint property, etc.) deteriorate. On the other hand, in an embodiment, the functional layer FL formed by providing the thermosetting coating solution ECL (see FIG. 7) including the UV absorber in an amount of about 1 w % to about 10 wt % with respect to the total weight of the thermosetting coating solution ECL (see FIG. 7) and the display device DD including the functional layer FL make it possible to ensure excellent reliability.

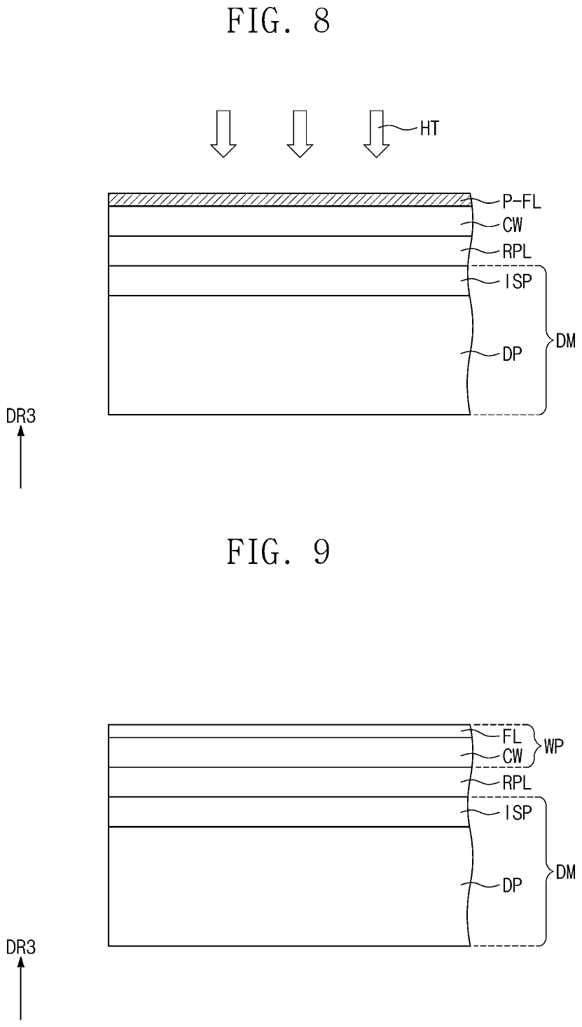

In an embodiment, the thermosetting coating solution ECL (see FIG. 7) is cured by heat HT (see FIG. 8) and is substantially nonreactive to light. The wording “substantially nonreactive” means that the reaction for causing physical and/or chemical properties to be substantially changed does not occur.

In an embodiment, the functional layer FL formed from the thermosetting coating solution ECL (see FIG. 7) may include a base resin, a fluorine-containing compound, and a UV absorber. The base resin may include an acryl-based resin. The functional layer FL including a fluorine-containing compound may exhibit an excellent anti-fingerprint property. The functional layer FL including an acryl-based resin may exhibit excellent wear resistance, chemical resistance, and scratch resistance.

The UV absorber may absorb light having a wavelength range of about 300 nm to about 400 nm. In an embodiment, the UV absorber may include an organic material. The UV absorber may not include an inorganic material. For example, the UV absorber may include at least one of a stilbene-based derivative, a phenylenevinylene-based derivative, a benzoxazole-based derivative, a benzotriazole-based derivative, a benzophenone-based derivative, or a triazine-based derivative.

In an embodiment, in a typical display device, a functional layer which performs functions of anti-fingerprint and/or hard coating is formed by providing a photocurable coating solution which is cured by light. Since a coating window including an epoxy-based resin has weak hardness and is vulnerable to yellowing, the functional layer is formed from a functional material including an acryl-based resin, a UV absorber, etc., so as to improve the hardness of the coating window and to prevent the coating window from yellowing. The functional material is cured by ultraviolet rays, and the UV absorber is limited to an amount of less than about 1 wt % with respect to the total weight of the functional material. Since the UV absorber absorbs light provided to cure the functional material, the functional layer FL is not formed when the UV absorber is included in an amount of about 1 wt % or more. On the other hand, in an embodiment, since the functional layer FL is formed from the thermosetting coating solution ECL (see FIG. 7) which is cured by heat, the UV absorber may be provided in an amount of about 1 wt % or more. In an embodiment, since the functional layer FL including the UV absorber in an amount of about 1 wt % or more is formed directly on the coating window CW, the coating window CW, etc., are prevented from yellowing, and thus the display device DD may have improved reliability.

FIG. 4 is a cross-sectional view illustrating a display module DM, according to an embodiment. FIG. 4 may be a cross-sectional view describing, in more detail, a configuration of the display module DM illustrated in FIG. 3.

In an embodiment, the display panel DP may include the pixel PX (see FIG. 2). The pixel PX (see FIG. 2) may include a transistor TR and a light-emitting element ED. The transistor TR and the light-emitting element ED may be disposed on the base layer BS. FIG. 4 illustrates one transistor TR, but the pixel PX (see FIG. 2) may substantially include at least one capacitor and a plurality of transistors for driving the light-emitting element ED.

In an embodiment, the circuit layer DP-CL may be disposed on the base layer BS. The circuit layer DP-CL may include a shielding electrode BML, a transistor TR, a connection electrode CNE, and a plurality of insulating layers BFL and INS1 to INS6. The plurality of insulating layers BFL and INS1 to INS6 may include a buffer layer BFL and first to sixth insulating layers INS1 to INS6, respectively. However, the stacked structure of the circuit layer DP-CL illustrated in FIG. 4 is presented as an example, and the stacked structure of the circuit layer DP-CL may be changed according to a configuration of the pixel PX (see FIG. 2) and a process for the circuit layer DP-CL.

In an embodiment, the shielding electrode BML may be disposed on the base layer BS. The shielding electrode BML may overlap the transistor TR. The shielding electrode BML may block light incident onto the transistor TR from below the display panel DP to protect the transistor TR. The shielding electrode BML may include a conductive material. When a voltage is applied to the shielding electrode BML, a threshold voltage of the transistor TR disposed on the shielding electrode BML may be maintained. However, the invention is not limited thereto, and the shielding electrode BML may be a floating electrode. In another embodiment, the shielding electrode BML may be omitted.

In an embodiment, the buffer layer BFL may be disposed on the base layer BS and cover the shielding electrode BML. The buffer layer BFL may include an inorganic layer. The buffer layer BFL may improve a bonding force between the base layer BS and a semiconductor pattern or a conductive pattern, which is disposed on the buffer layer BFL.

In an embodiment, the transistor TR may include a source S1, a channel C1, a drain D1, and a gate G1. The source S1, the channel C1, and the drain D1 of the transistor TR may be formed from a semiconductor pattern. The semiconductor pattern of the transistor TR may include polysilicon, amorphous silicon, or a metal oxide. However, any material having semiconductor properties may be used without any limitation but is not limited to any one embodiment.

In an embodiment, the semiconductor pattern may include a plurality of regions divided according to a conductivity level. In the semiconductor pattern, a region, which is doped with a dopant or in which a metal oxide is reduced, may have a high conductivity, and may serve substantially as a source electrode and a drain electrode of the transistor TR. A highly conductive region of the semiconductor pattern may correspond to the source S1 and the drain D1 of the transistor TR. In the semiconductor pattern, a region, which is undoped or lightly doped or which has a low conductivity due to a non-reduced metal oxide, may correspond to the channel C1 (or active) of the transistor TR.

In an embodiment, the first insulating layer INS1 may cover the semiconductor pattern of the transistor TR and may be disposed on the buffer layer BFL. The gate G1 of the transistor TR may be disposed on the first insulating layer INS1. The gate G1 may overlap the channel C1 of the transistor TR. The gate G1 may function as a mask during the process of doping the semiconductor pattern of the transistor TR.

In an embodiment, the second insulating layer INS2 may cover the gate G1 and be may disposed on the first insulating layer INS1. The third insulating layer INS3 may be disposed on the second insulating layer INS2.

In an embodiment, the connection electrode CNE may include a first connection electrode CNE1 and a second connection electrode CNE2 which electrically connect the transistor TR and the light-emitting element ED. However, an embodiment of the connection electrode CNE which electrically connects the transistor TR to the light-emitting element ED is not limited to the configuration described above. In another embodiment, either of the first connection electrode CNE1 or the second connection electrode CNE2 may be omitted, or an additional connection electrode may be further included.

In an embodiment, the first connection electrode CNE1 may be disposed on the third insulating layer INS3. The first connection electrode CNE1 may be connected to the drain D1 via a first contact hole CH1 passing through the first to third insulating layers INS1 to INS3, respectively. The fourth insulating layer INS4 may cover the first connection electrode CNE1 and may be disposed on the third insulating layer INS3. The fifth insulating layer INS5 may be disposed on the fourth insulating layer INS4.

In an embodiment, the second connection electrode CNE2 may be disposed on the fifth insulating layer INS5. The second connection electrode CNE2 may be connected to the first connection electrode CNE1 via a second contact hole CH2 passing through the fourth and fifth insulating layers INS4 and INS5, respectively. The sixth insulating layer INS6 may cover the second connection electrode CNE2 and may be disposed on the fifth insulating layer INS5.

In an embodiment, the first to sixth insulating layers INS1 to INS6, respectively, may each include an inorganic layer or an organic layer. For example, the inorganic layer may include at least one of aluminum oxide, titanium oxide, silicon oxide, silicon oxynitride, zirconium oxide, or hafnium oxide. The organic layer may include at least one of an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, or a perylene-based resin.

In an embodiment, the display element layer DP-ED may include a pixel-defining film PDL and the light-emitting element ED. The light-emitting element ED may include a first electrode AE, a hole control layer HCL, a light-emitting layer EML, an electron control layer TCL, and a second electrode CE.

In an embodiment, the first electrode AE may be disposed on the sixth insulating layer INS6. The first electrode AE may be connected to the second connection electrode CNE2 via a third contact hole CH3 passing through the sixth insulating layer INS6. The first electrode AE may be electrically connected to the drain D1 of the transistor TR via the first and second connection electrodes CNE1 and CNE2, respectively.

In an embodiment, the first electrode AE may be formed of a metal material, metal alloy, or conductive compound. The first electrode AE may be an anode or a cathode. However, the invention is not limited thereto. Also, the first electrode AE may be a pixel electrode. The first electrode AE may be a transmissive electrode, a transflective electrode, or a reflective electrode. The first electrode AE may include: at least one selected from among Ag, Mg, Cu, Al, Pt, Pd, Au, Ni, Nd, Ir, Cr, Li, Ca, LiF, Mo, Ti, W, In, Sn, or Zn; a compound of two or more materials selected from there-among; a mixture of two or more materials selected from there-among; or an oxide thereof.

In an embodiment, when the first electrode AE is the transmissive electrode, the first electrode AE may include a transparent metal oxide, for example, indium tin oxide (ITO), indium zinc oxide (IZO), zinc oxide (ZnO), indium tin zinc oxide (ITZO), and the like. When the first electrode AE is the transflective electrode or the reflective electrode, the first electrode AE may include Ag, Mg, Cu, Al, Pt, Pd, Au, Ni, Nd, Ir, Cr, Li, Ca, LiF/Ca (stacked structure of LiF and Ca), LiF/Al (stacked structure of LiF and Al), Mo, Ti, W, or a compound or mixture thereof (for example, a mixture of Ag and Mg). In another embodiment, the first electrode AE may have a multi-layered structure including a reflective film or a transflective film, which is formed of the above-described materials, and a transparent conductive film formed of indium tin oxide (ITO), indium zinc oxide (IZO), zinc oxide (ZnO), indium tin zinc oxide (ITZO), and the like. For example, the first electrode AE may have a three-layered structure of ITO/Ag/ITO, but is not limited thereto. In addition, the invention is not limited thereto, and the first electrode AE may include the above-described metal materials, a combination of two or more metal materials selected from there-among, oxides of the above-described metal materials, or the like.

In an embodiment, the pixel-defining film PDL may be disposed on the sixth insulating layer INS6. A light-emitting opening PX_OP which exposes a portion of the first electrode AE may be defined in the pixel-defining film PDL. A portion, of the first electrode AE, which is exposed by the light-emitting opening PX_OP may be defined as a light-emitting region LA.

In an embodiment, a region, in which the pixel-defining film PDL is disposed, may correspond to a light-blocking region NLA. The light-blocking region NLA may surround the light-emitting region LA in an active region AA-DM.

In an embodiment, a hole control layer HCL may be disposed on the first electrode AE and the pixel-defining film PDL. The hole control layer HCL may be provided as a common layer overlapping the light-emitting region LA and the light-blocking region NLA. The hole control layer HCL may include at least one of a hole transport layer, a hole injection layer, or an electron blocking layer. The hole control layer HCL may include a typical hole injection material and/or a typical hole transport material.

In an embodiment, the light-emitting layer EML may be disposed on the hole control layer HCL. The light-emitting layer EML may be disposed in a region corresponding to the light-emitting opening PX_OP. In another embodiment, the light-emitting layer EML may be provided as a common layer. The light-emitting layer EML may include an organic light-emitting material and/or an inorganic light-emitting material. The light-emitting layer EML may emit light having one color of red, green, or blue.

In an embodiment, the electron control layer TCL may be disposed on the light-emitting layer EML. The electron control layer TCL may be provided as a common layer overlapping the light-emitting region LA and the light-blocking region NLA. The electron control layer TCL may include at least one of an electron transport layer, an electron injection layer, or a hole blocking layer. The electron control layer TCL may include a typical electron injection material and/or a typical electron transport material.

In an embodiment, the second electrode CE may be disposed on the electron control layer TCL. The second electrode CE may be provided as a common layer overlapping the light-emitting region LA and the light-blocking region NLA. The second electrode CE may be disposed, in common, in the pixels PX (see FIG. 2) and may apply voltages to the pixels PX (see FIG. 2).

In an embodiment, the second electrode CE may be a common electrode. The second electrode CE may be a cathode or an anode but the invention is not limited thereto. For example, when the first electrode AE is an anode, the second electrode CE may be a cathode, and when the first electrode AE is a cathode, the second electrode CE may be an anode.

In an embodiment, the second electrode CE may be a transmissive electrode, a transflective electrode, or a reflective electrode. When the second electrode CE is the transmissive electrode, the second electrode CE may include a transparent metal oxide, for example, indium tin oxide (ITO), indium zinc oxide (IZO), zinc oxide (ZnO), indium tin zinc oxide (ITZO), and the like.

In an embodiment, when the second electrode CE is the transflective electrode or the reflective electrode, the second electrode CE may include Ag, Mg, Cu, Al, Pt, Pd, Au, Ni, Nd, Ir, Cr, Li, Ca, LiF/Ca, LiF/Al, Mo, Ti, Yb, W, or a compound or mixture thereof (for example, AgMg, AgYb, or MgYb). In another embodiment, the second electrode CE may have a multi-layered structure including a reflective film or a transflective film, which is formed of the above-described materials, and a transparent conductive film formed of indium tin oxide (ITO), indium zinc oxide (IZO), zinc oxide (ZnO), indium tin zinc oxide (ITZO), and the like. For example, the second electrode CE may include the above-described metal materials, a combination of two or more metal materials selected from there-among, oxides of the above-described metal materials, or the like.

In an embodiment, an encapsulation layer TFE may be disposed on the second electrode CE and may cover the light-emitting element ED. The encapsulation layer TFE may include a plurality of thin films. For example, the encapsulation layer TFE may include inorganic films, disposed on the second electrode CE, and an organic film may be disposed between the inorganic films. The inorganic film may protect the light-emitting element ED against moisture/oxygen, and the organic film may protect the light-emitting element ED against foreign substances such as dust particles.

In an embodiment, the input-sensing layer ISP may include a first sensing-insulating layer IL1, a second sensing-insulating layer IL2, and a third sensing-insulating layer IL3. The input-sensing layer ISP may include at least one conductive layer disposed on the sensing-insulating layers IL1, IL2, IL3. The input-sensing layer ISP may include a first conductive layer CDL1, and a second conductive layer CDL2.

In an embodiment, the first sensing-insulating layer ILI may be disposed on the encapsulation layer TFE. The first sensing-insulating layer IL1 may include at least one inorganic insulating layer. The first sensing-insulating layer IL1 may be in contact with the encapsulation layer TFE. In another embodiment, the first sensing-insulating layer IL1 may be omitted, and in this case, the first conductive layer CDL1 may be in contact with the encapsulation layer TFE.

In an embodiment, the first conductive layer CDL1 may be disposed on the first sensing-insulating layer IL1. The first conductive layer CDL1 may include a plurality of first conductive patterns. The plurality of first conductive patterns may be disposed on the first sensing-insulating layer IL1. The second sensing-insulating layer IL2 may be disposed on the first sensing-insulating layer IL1 to cover at least a portion of the first conductive layer CDL1.

In an embodiment, the second conductive layer CDL2 may be disposed on the second sensing-insulating layer IL2. The second conductive layer CDL2 may include a plurality of second conductive patterns. The plurality of second conductive patterns may be disposed on the second sensing-insulating layer IL2. The plurality of second conductive patterns may be respectively connected to the plurality of first conductive patterns via a contact hole formed in the second sensing-insulating layer IL2.

In an embodiment, the plurality of first conductive patterns of the first conductive layer CDL1 and the plurality of second conductive patterns of the second conductive layer CDL2 may each be disposed to correspond to the light-blocking region NLA. The plurality of first conductive patterns of the first conductive layer CDL1 and the plurality of second conductive patterns of the second conductive layer CDL2 may each correspond to a mesh pattern.

In an embodiment, the third sensing-insulating layer IL3 may be disposed on the second sensing-insulating layer IL2 and cover the second conductive layer CDL2. The second sensing-insulating layer IL2 and the third sensing-insulating layer IL3 may each include an inorganic insulating layer or an organic insulating layer.

In an embodiment, the first conductive layer CDL1 and the second conductive layer CDL2 may each have a single-layered structure or a multi-layered structure in which layers are stacked along the third direction DR3. The conductive layers CDL1 and CDL2 having a single-layered structure may each include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnO), and indium zinc tin oxide (IZTO). Also, the transparent conductive layer may include a conductive polymer such as PEDOT, a metal nanowire, graphene, and the like.

In an embodiment, the conductive layers CDL1 and CDL2 having a multi-layered structure may include metal layers. For example, the metal layers may have a three-layered structure of titanium (Ti)/aluminum (Al)/titanium (Ti). The conductive layers CDL1 and CDL2 having a multi-layered structure may include at least one metal layer and at least one transparent conductive layer.

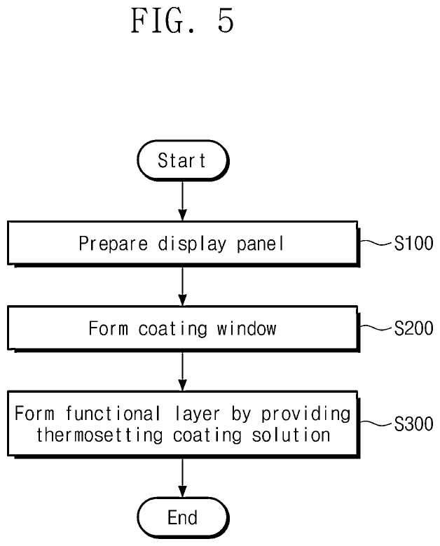

In an embodiment, the display device DD (see FIG. 3) may be formed through a method for manufacturing a display device. FIG. 5 is a flowchart illustrating a method for manufacturing a display device, according to an embodiment. FIGS. 6 to 9 are views schematically illustrating display device manufacturing steps, according to an embodiment. Hereinafter, with regard to the descriptions of FIGS. 5 to 9, the contents duplicated with those described with regards to the references of FIGS. 1 to 4 will not be explained again, and the following description will be mainly focused on the differences.

In an embodiment and referring to FIG. 5, a method for manufacturing the display device may include a step of preparing a display panel (S100), a step of forming a coating window (S200), and a step of forming a functional layer by providing a thermosetting coating solution (S300). A coating window CW (see FIG. 7) may be formed on a display panel DP (see FIG. 7). A functional layer FL (see FIG. 9) may be formed on the coating window CW (see FIG. 9).

In an embodiment and referring to FIG. 6, a coating composition CAW may be provided to form the coating window CW (see FIG. 7) on the display module DM including the display panel DP. Specifically, the coating composition CAW may be directly disposed on an optical layer RPL disposed on the display module DM. In another embodiment, when the optical layer RPL is omitted, the coating composition CAW may be directly disposed on the display module DM. The coating composition CAW may be directly disposed on a member (for example, optical layer) constituting the display device DD (see FIG. 3). The method for manufacturing the display device, according to an embodiment, may include the step of forming the coating window CW (see FIG. 7) by directly disposing the coating composition CAW on a member (for example, optical layer) constituting the display device DD (see FIG. 3), thereby simplifying a manufacturing process and reducing manufacturing costs. Therefore, the method for manufacturing the display device, according to an embodiment, may exhibit excellent manufacturing efficiency.

In an embodiment, the coating composition CAW may include an epoxy-based resin. FIG. 6 illustrates that the coating composition CAW is provided through a nozzle NZ, but an apparatus for providing the coating composition CAW is not limited thereto. Light is provided to the coating composition CAW applied on the display module DM, and the coating composition CAW is cured by the light to form the coating window CW (see FIG. 7). Although not illustrated, the method for manufacturing the display device, according to an embodiment, may further include a step of forming a printing layer before providing the coating composition CAW. As described above, the printing layer may be formed to correspond to the bezel region BZA (see FIG. 2).

In an embodiment and referring to FIG. 7, a thermosetting coating solution ECL may be disposed on the coating window CW. The thermosetting coating solution ECL may be directly disposed on the coating window CW.

In an embodiment, the thermosetting coating solution ECL may be provided through roll coating, silk screen coating, spray coating, or slit coating. FIG. 7 exemplarily illustrates that the thermosetting coating solution ECL is provided through a sprayer SY, but the invention is not limited thereto.

In an embodiment, the thermosetting coating solution ECL may include a UV absorber in an amount of about 1 wt % to about 10 wt % with respect to the total weight of the thermosetting coating solution ECL. The functional layer FL (see FIG. 9), formed from the thermosetting coating solution ECL including about 1 wt % to about 10 wt % of the UV absorber, may exhibit excellent reliability.

In an embodiment, the UV absorber may include an organic material. For example, the UV absorber may include at least one of a stilbene-based derivative, a phenylenevinylene-based derivative, a benzoxazole-based derivative, a benzotriazole-based derivative, a benzophenone-based derivative, or a triazine-based derivative.

In an embodiment, the thermosetting coating solution ECL may include a base resin and a fluorine-containing compound. The thermosetting coating solution ECL may include an acryl-based resin as the base resin. However, the invention is not limited thereto, and the thermosetting coating solution ECL may further include an additive or the like known in the art, as long as it is not degrading to the properties of the functional layer FL (for example, wear resistance, scratch resistance, and the like).

In an embodiment and referring to FIG. 8, heat HT may be provided to a preliminary functional layer P-FL formed by providing the thermosetting coating solution ECL (see FIG. 7). Referring to FIGS. 8 and 9, the functional layer FL may be formed by curing the preliminary functional layer P-FL. The degree of cure of the preliminary functional layer P-FL may be about 90% or more. The functional layer FL may be formed by curing the preliminary functional layer P-FL to a degree of cure of about 90% or more. The preliminary functional layer P-FL may be cured at a temperature of about 20° C. to about 80° C. The heat HT may be provided to set a temperature condition of about 20° C. to about 80° C. When the temperature condition of about 20° C. to about 80° C. is already set before providing the heat HT, the heat HT may not be provided.

In an embodiment, at a temperature of less than about 20° C., the curing of the preliminary functional layer P-FL may not be performed easily, and at a temperature of greater than about 80° C., a component (for example, display panel) of the display device disposed below the preliminary functional layer P-FL is damaged. In another embodiment, the method for manufacturing the display device may include the step of curing the preliminary functional layer P-FL at a temperature of about 20° C. to about 80° C., thereby easily curing the preliminary functional layer P-FL and preventing a member such as the display panel DP from being damaged during a manufacturing process.

In an embodiment, the method for manufacturing the display device may include a step of forming a functional layer FL by disposing a thermosetting coating solution on the coating window CW. The thermosetting coating solution may include a UV absorber in an amount of about 1 wt % to about 10 wt %, and the UV absorber may be an organic material. The method for manufacturing the display device, according to an embodiment, may include the step of forming the functional layer FL from the thermosetting coating solution which is cured by heat, and thus ensure excellent reliability. A display device which is manufactured through the method for manufacturing the display device, according to an embodiment, including the step of forming the functional layer FL from the thermosetting coating solution cured by heat, may exhibit excellent reliability. The functional layer FL formed from the thermosetting coating solution may include a UV absorber in an amount of about 1 wt % or more, thereby making it possible to prevent a coating window CW, etc., from being damaged by ultraviolet rays.

In an embodiment, a display device may include a functional layer FL including an ultraviolet absorber, thereby exhibiting excellent reliability.

In an embodiment, a method for manufacturing a display device may include forming a functional layer FL from a thermosetting coating solution including an ultraviolet absorber, thereby exhibiting excellent reliability.

Although various embodiments of the invention have been described, it is understood that the invention should not be limited to these embodiments but various changes and modifications can be made by one of ordinary skill in the art within the spirit and scope of the invention.

The technical scope of the inventive concept is not limited to the contents described in the detailed description of the specification. Moreover, the embodiments or parts of the embodiments may be combined in whole or in part without departing from the scope of the invention.

What is claimed is:

1. A display device comprising:
a display panel;
a coating window disposed on the display panel; and
a functional layer disposed on the coating window and formed from a thermosetting coating solution,
wherein the functional layer includes an ultraviolet (UV) absorber in an amount of about 1 wt % to about 10 wt % with respect to a total weigh of the functional layer, and
wherein the UV absorber includes an organic material.

2. The display device of claim 1, wherein the functional layer further comprises a base resin and a fluorine-containing compound.

3. The display device of claim 2, wherein the base resin comprises an acryl-based resin.

4. The display device of claim 1, wherein the UV absorber comprises at least one of a stilbene-based derivative, a phenylenevinylene-based derivative, a benzoxazole-based derivative, a benzotriazole-based derivative, a benzophenone-based derivative, or a triazine-based derivative.

5. The display device of claim 1, wherein the functional layer has a pencil hardness of about 6 H or more.

6. The display device of claim 1, wherein the functional layer has a yellow index of about 1 or less.

7. The display device of claim 1, wherein the functional layer has a transmittance of about 90% or more with respect to light having a visible light wavelength range.

8. The display device of claim 1, wherein the functional layer is a single layer.

9. The display device of claim 1, wherein the functional layer is directly disposed on the coating window.

10. The display device of claim 1, wherein the coating window comprises an epoxy-based resin.

11. A method for manufacturing a display device, the method comprising:
preparing a display panel;
forming a coating window on the display panel; and
forming a functional layer by disposing a thermosetting coating solution on the coating window,
wherein the thermosetting coating solution includes a UV absorber in an amount of about 1 wt % to about 10 wt % with respect to the total weight of the thermosetting coating solution, and
wherein the UV absorber includes an organic material.

12. The method of claim 11, wherein the thermosetting coating solution is directly disposed on the coating window.

13. The method of claim 11, wherein the thermosetting coating solution further comprises a base resin and a fluorine-containing compound.

14. The method of claim 13, wherein the base resin comprises an acryl-based resin.

15. The method of claim 11, wherein the UV absorber comprises at least one of a stilbene-based derivative, a phenylenevinylene-based derivative, a benzoxazole-based derivative, a benzotriazole-based derivative, a benzophenone-based derivative, or a triazine-based derivative.

16. The method of claim 11, wherein the forming of the functional layer comprises:
forming a preliminary functional layer by disposing the thermosetting coating solution on the coating window; and
forming the functional layer by curing the preliminary functional layer, wherein
the curing of the preliminary functional layer is performed at a temperature range of about 20° C. to about 80° C.

17. The method of claim 16, wherein in the forming of the preliminary functional layer, a curing rate is about 90% or more.

18. The method of claim 11, wherein the thermosetting coating solution is provided through roll coating, silk screen coating, spray coating, or slit coating.

19. The method of claim 11, wherein the coating window is formed by disposing a coating composition on the display panel.

20. The method of claim 19, wherein the coating composition comprises an epoxy-based resin.
